(19) United States
(12) Patent Application Publication
(10) Pub. No.: US 2022/0117112 A1
(43) Pub. Date: Apr. 14, 2022

(54) ENHANCED ELECTRONIC PACKAGE THERMAL DISSIPATION WITH IN-SITU TRANSPIRATION COOLING AND REDUCED THERMAL INTERSTITIAL RESISTANCE

(71) Applicant: Intel Corporation, Santa Clara, CA (US)

(72) Inventors: Prabhakar SUBRAHMANYAM, San Jose, CA (US); Ying-Feng PANG, San Jose, CA (US); Yi XIA, Campbell, CA (US); Muhammad AHMAD, Fremont, CA (US)

(21) Appl. No.: 17/068,333

(22) Filed: Oct. 12, 2020

(51) Int. Cl. H05K 7/20; H01L 23/367

(52) U.S. Cl. CPC H05K 7/20163; H01L 23/3677

(57) ABSTRACT

Embodiments disclosed herein include heatsinks with transpiration cooling features. In an embodiment, a heatsink comprises a body with a first surface, a second surface, and a sidewall surface connecting the first surface to the second surface. In an embodiment, a first hole is formed into the first surface, where the first hole terminates before reaching the second surface. In an embodiment, the heatsink further comprises a second hole into the sidewall surface, where the second hole intersects the first hole.

### TECHNICAL FIELD

Embodiments of the present disclosure relate to semiconductor devices, and more particularly to electronic packages with heatsinks that comprise transpiration cooling features.

### BACKGROUND

One typical solution for providing cooling of electronic packages is through air-cooling. Air-cooling is very well understood and has a relatively simple design. In an air-cooling architecture, the heatsink comprises fins that extend up from a solid body. Thermal energy passes from the electronic package to the solid body and into the fins. Air is passed over the fins to provide convection cooling. Cost, reliability, and complexity considerations make air-cooling an attractive design choice over other cooling solutions.

However, with the increase in package power density and/or package thermal design power (TDP), typical air-cooling architectures with a solid body may not meet the cooling design specifications. In order to meet the design specifications, heat pipes or vapor chambers replace the solid base, or liquid cooling is used instead of air. When the base is replaced with a heat pipe or vapor chamber, the base needs to be considerably larger than the heat source in order to be thermally effective. This usually results in a large heatsink form factor. Heat pipe and vapor chambers also suffer shape limitations and minimize design flexibility. Liquid cooling, while more efficient at heat removal than air cooling, is more expensive to implement, and liquid cooling is susceptible to leaks.

### BRIEF DESCRIPTION OF THE DRAWINGS

FIG. 1A is a cross-sectional illustration of a heatsink with holes for transpiration cooling, in accordance with an embodiment.

FIG. 1B is a plan view illustration of a heatsink with holes for transpiration cooling, in accordance with an embodiment.

FIG. 2A is a cross-sectional illustration of a heatsink with tapered holes for transpiration cooling, in accordance with an embodiment.

FIG. 2B is a cross-sectional illustration of a heatsink with stepped holes for transpiration cooling, in accordance with an embodiment.

FIG. 3A is a cross-sectional illustration of a heatsink with first holes intersecting second holes, and third holes intersecting to grooves, in accordance with an embodiment.

FIG. 3B is a cross-sectional illustration of a heatsink with holes intersecting grooves, in accordance with an embodiment.

FIG. 4A is a cross-sectional illustration of a heatsink with holes for transpiration cooling and a highly ordered pyrolytic graphite (HOPG) coating over a surface of the heatsink, in accordance with an embodiment.

FIG. 4B is a cross-sectional illustration of a heatsink with transpiration cooling features and an HOPG coating over a surface of the heatsink, in accordance with an embodiment.

FIG. 5A is a cross-sectional illustration of an electronic package with a heat spreader between the dies and the heatsink, in accordance with an embodiment.

FIG. 5B is a cross-sectional illustration of an electronic package with a heatsink directly attached to the dies by a thermal interface material (TIM), in accordance with an embodiment.

FIG. 5C is a cross-sectional illustration of an electronic package with a heatsink with an HOPG coating directly attached to the dies by a TIM, in accordance with an embodiment.

FIG. 6 is a schematic of a computing device built in accordance with an embodiment.

### EMBODIMENTS OF THE PRESENT DISCLOSURE

Described herein are electronic packages with heatsinks that comprise transpiration cooling features, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, thermal design specifications of some high performance electronic packages have outpaced the cooling capability of simple air cooling architectures. As such, advanced cooling architectures, (e.g., heat pipes, vapor chambers, liquid cooling, etc.) have replaced air cooling architectures in many advanced products. However, the use of such advanced cooling architectures have form factor limitations, and increases the complexity and cost of the heatsink. Accordingly, embodiments described herein provide heatsinks that utilize transpiration cooling in order to enhance the performance of heatsinks with solid bodies. Instead of replacing the solid body with a vapor chamber or heat pipe, holes are formed into the solid body to allow for transpiration cooling.

Transpiration cooling is a thermodynamic process where cooling is achieved by a process of moving a liquid or gas through the wall of a structure to absorb some portion of the heat energy from the structure. In the case of heatsinks described herein, vertical holes are provided into a first surface of the heatsink (e.g., between fins). The vertical holes may intersect lateral holes that are embedded in the body of the heatsink. Air (e.g., from a fan) travels down the vertical holes and exits the heatsink through the lateral holes.

In some embodiments, one or more of the vertical holes may instead intersect a groove on the second (backside) surface of the heatsink. In such embodiments, the cooling fluid (e.g., air from a fan) can also directly contact a surface of the device being cooled before exiting the heatsink. As such, the device being cooled is subject to both conductive cooling (from the interface between the device being cooled and the heatsink) and transpiration cooling (from the cooling fluid passing through the grooves).

In yet another embodiment, a highly ordered pyrolytic graphite (HOPG) coating may be provided over the second surface of the heatsink. The HOPG coating has a high thermal conductivity and can function as a heat spreader. This aids in the spreading of heat from a high-power density or high power package to the heatsink base, thus lowering the temperature. In some embodiments, the use of an HOPG coating may allow for the removal of a dedicated heat spreader. Additionally, embodiments disclosed herein include a heatsink with both transpiration cooling features and an HOPG coating.

The use of transpiration cooling provides significant thermal improvements compared to a solid body heatsink. For example, the presence of transpiration cooling features, such as those described herein, may provide an approximately 30% reduction in substrate temperature in temperature reduction compared to a solid body heatsink operating under the same boundary conditions. For example it has been shown that, at a thermal design power (TDP) of 60 W with a power density of approximately 0.25 W/mm², the traditional solid body heatsink has a package temperature of approximately 65° C. and the transpiration cooled package substrate has a temperature of approximately 45° C.

HOPG coatings have also been shown to significantly improve thermal performance. Particularly, at a power density of approximately 0.25 W/mm² an approximately 6.5% reduction in substrate temperature is shown over a transpiration heatsink without the HOPG coating. Furthermore, higher power densities result in even more improvement. For example, at a power density of approximately 1.25 W/mm², an approximately 17% reduction in substrate temperature is shown over a transpiration heatsink without the HOPG coating.

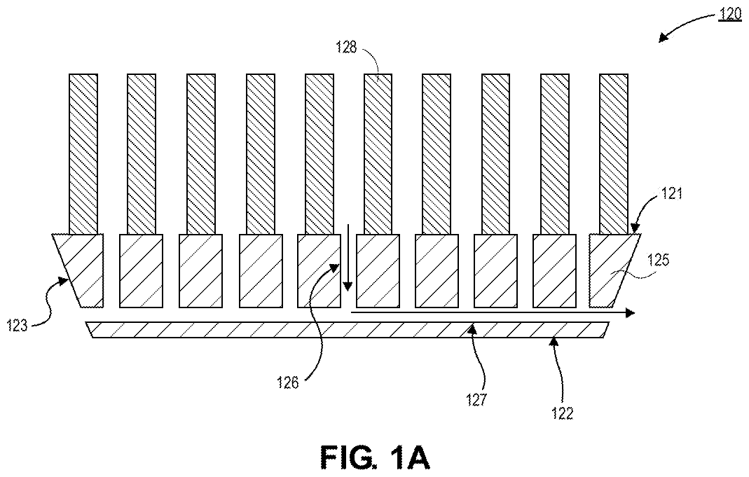

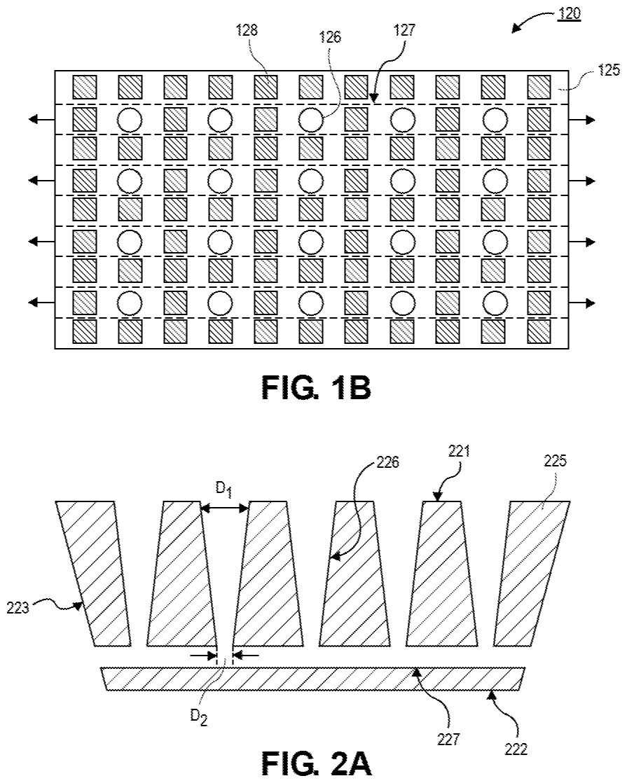

Referring now to FIG. 1A, a cross-sectional illustration of a heatsink 120 is shown, in accordance with an embodiment. In an embodiment, the heatsink 120 may comprise a body 125. The body 125 of the heatsink may be a thermally conductive material, such as copper, aluminum, or the like. The body 125 comprises a first surface 121, a second surface 122, and sidewall surfaces 123. The first surface 121 may be considered a front side surface and the second surface 122 may be considered a backside surface. The second surface 122 may be the surface contacting the device being cooled, a heat spreader, or the like.

In an embodiment, a plurality of fins 128 may extend up from the first surface 121. The fins 128 may be a thermally conductive material, such as copper, aluminum, or the like. The fins 128 may be a monolithic structure with the body 125 in some embodiments. In other embodiments, the fins 128 may be discrete components secured to the body 125. The fins 128 may be elongated (into and out of the plane of FIG. 1A) or the fins 128 may be posts.

In an embodiment, the body 125 comprises transpiration cooling features. In an embodiment, the transpiration cooling features comprise vertical holes 126 and lateral holes 127. The vertical holes 126 are formed into the first surface 121 of the body between the fins 128. The vertical holes 126 and the lateral holes 127 may have a dimension suitable for transpiration cooling. For example, a diameter of the vertical holes 126 and the lateral holes 127 may be between approximately 0.5 mm and approximately 2 mm. In the illustrated embodiment, the vertical holes 126 may have a constant diameter. That is, the sidewalls of the vertical holes 126 may be substantially vertical.

In a particular embodiment, the vertical holes 126 do not pass through an entire thickness of the body. For example, the vertical holes 126 may terminate at the lateral holes 127. That is, the vertical holes 126 may intersect the lateral holes 127. The lateral holes 127 may extend across the body 125 from a first sidewall 123 to a second sidewall 123 opposite from the first sidewall 123. However, it is to be appreciated that the lateral holes 127 may only exit the body 125 at a single sidewall 123 in some embodiments. The lateral holes 127 may be referred to as being embedded in the body 125. That is, bottom surfaces of the lateral holes 127 are spaced away from the second surface 122 by a portion of the body 125. In an embodiment, the vertical holes 126 may be substantially orthogonal to the lateral holes 127. As indicated by the arrows, air (e.g., from a fan) flows into the vertical holes 126 down towards the lateral holes 127. Once reaching the lateral holes 127, the air flows along the lateral holes 127 to exit the body 125 out the sidewalls 123. In this manner, heat energy from the interior of the body 125 may be transferred out the side of the body 125 in order to reduce the temperature of the body 125.

The use of transpiration cooling using the vertical holes 126 and the lateral holes 127 provides significant thermal improvements compared to a solid body heatsink. For example, the presence of transpiration cooling features may provide an approximately 30% reduction in substrate temperature in temperature reduction compared to a solid body heatsink operating under the same boundary conditions. For example it has been shown that, at a thermal design power (TDP) of 60 W with a power density of approximately 0.25 W/mm², the traditional solid body heatsink has a package temperature of approximately 65° C. and the transpiration cooled package substrate has a temperature of approximately 45° C.

Referring now to FIG. 1B a plan view illustration of a portion of a heatsink 120 is shown, in accordance with an embodiment. As shown, the vertical holes 126 are arranged in an array of columns and rows between the fins 128. Each row of vertical holes 126 intersect a single one of the lateral holes 127 (indicated with dashed lines to show they are buried in the body 125). That is, a plurality of vertical holes 126 may intersect a single one of the lateral holes 127. In the illustrated embodiment, each of the lateral holes 127 are substantially parallel to each other. However, it is to be appreciated that lateral holes 127 may be formed with any relationship to each other. For example, two or more lateral holes 127 may intersect each other in some embodiments. As shown by the arrows, air that passes into the vertical holes 126 exits the body 125 through the sides of the body 125.

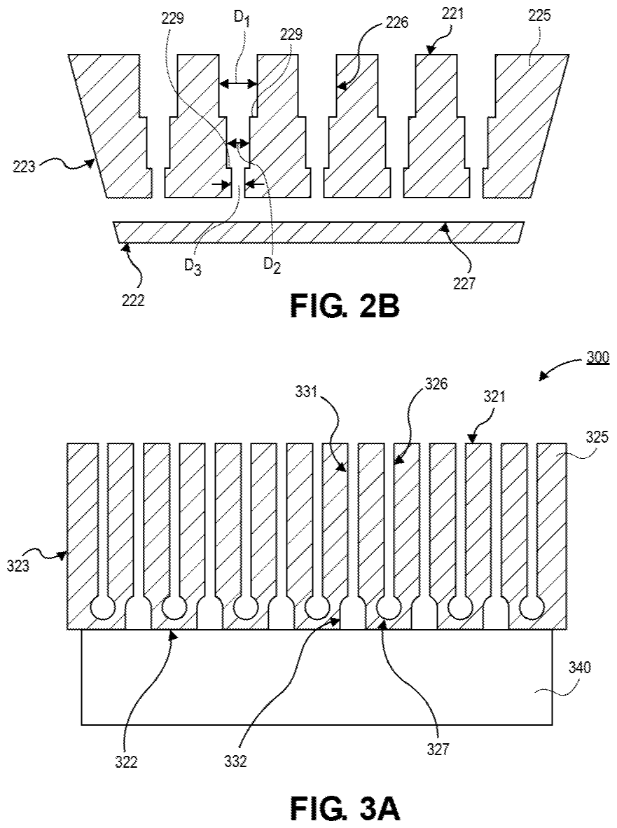

Referring now to FIG. 2A, a cross-sectional illustration of the body 225 of a heatsink is shown, in accordance with an embodiment. The body 225 has a first surface 221, a second surface 222, and sidewall surfaces 223. As shown in FIG. 2A, the vertical holes 226 have a tapered profile. The tapered profile includes a first diameter D₁ proximate to the first surface 221 and a second diameter D₂ proximate to the lateral hole 227. The second diameter D₂ may be smaller than the first diameter D₁. Reducing the diameter of the vertical holes 226 increases the flowrate of the cooling gas that passes through the vertical holes 226. As such, enhanced transpiration cooling is provided. In an embodiment, the first diameter D₁ may be approximately 2 mm and the second diameter D₂ may be approximately 0.5 mm. In an embodiment, the tapered vertical holes 226 may be formed with any suitable machining process. In a particular embodiment, the tapered vertical holes 226 may be manufactured with a tapered drill bit.

Referring now to FIG. 2B, a cross-sectional illustration of a body 225 of a heatsink is shown, in accordance with an additional embodiment. The body 225 may comprise vertical holes 226 that have a stepped profile. The stepped profile includes one or more steps 229 as the vertical hole 226 transitions from a first diameter D₁ to a smaller second diameter D₂ or third diameter D₃. Reducing the diameter of the vertical hole 226 results in an increase in the flow rate of the cooling gas, and provides improved transpiration cooling of the body 225. In an embodiment, the first diameter D₁ may be approximately 2 mm and the third diameter D₃ may be approximately 0.5 mm. The stepped profile may be formed with any suitable machining process. For example, a first drill bit with the third diameter D₃ may be used to form a hole to the depth of the lateral hole 227, a second drill bit with the second diameter D₂ may be used to expand the width of the hole to the depth of the bottom step 229, and a third drill bit with the first diameter D₁ may be used to expand the width of the hole to the depth of the top step 229. While the dimension of the vertical holes 226 in FIGS. 2A and 2B are referred to as a “diameter”, it is to be appreciated that non-circular vertical holes 226 may also be used. In such case D₁ and D₂ may refer to a width of the vertical holes 226, or any other suitable dimension.

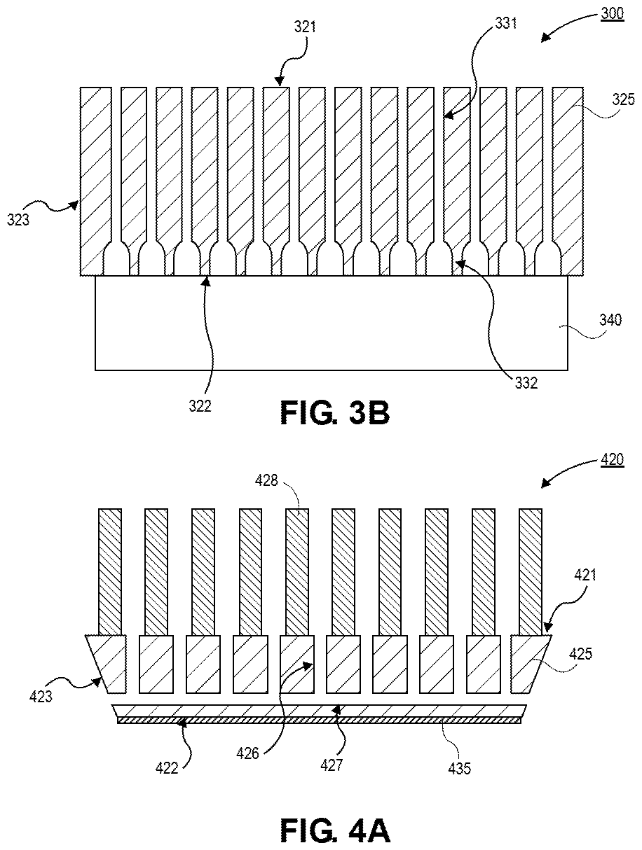

Referring now to FIG. 3A, a cross-sectional illustration of an electronic package 300 is shown, in accordance with an embodiment. In an embodiment, the electronic package 300 comprises a heatsink and a device 340 that is cooled by the heatsink. The heatsink comprises a thermally conductive body 325, such as a copper or aluminum material. The body 325 may comprise a first surface 321, a second surface 322, and sidewall surfaces 323. Fins (not shown) may be attached to the first surface 321 of the body 325 to provide improved cooling. In an embodiment, the device 340 may be an electronic package, such as a package substrate and a die. Some thermal components of the device 340, (e.g., thermal interface material (TIM) and a heat spreader) are omitted for simplicity. Those skilled in the art will appreciate that TIM and a heat spreader may be provided between a die and the second surface 322 of the body 325.

In an embodiment, first vertical holes 326 are provided into the first surface 321 of the body 325. The first vertical holes 326 may extend into the body 325 and intersect with lateral holes 327. The lateral holes 327 are embedded in the body 325 and extend into and out of the plane shown in FIG. 3A. Cooling fluid may enter the first vertical holes 326 and exit the body 325 through the lateral holes 327.

In an embodiment, second vertical holes 331 are also provided into the first surface 321 of the body 325. The second vertical holes 331 intersect with grooves 332 formed into the body 325. The grooves 332 are formed into the second surface 322 of the body 325. That is, cooling fluid that enters the second vertical holes 331 may also contact the top surface of the device 340 as the cooling fluid passes along the groove 332 towards the edge of the body 325. In an embodiment, the first vertical holes 326 and the second vertical holes 331 may be substantially similar to each other, with the exception of whether the hole intersect a lateral hole 327 or a groove 332. As such, the device 340 being cooled is subject to both conductive cooling (from the interface between the device 340 being cooled and the second surface 322) and transpiration cooling (from the cooling fluid passing through the grooves 332).

In an embodiment, the first vertical holes 326 and the second vertical holes 331 may have any suitable topography. In some embodiments, the profiles may be substantially vertical, as shown in FIG. 3A. However, in other embodiments, the first vertical holes 326 and the second vertical holes 331 may have tapered profiles (e.g., similar to the profile in FIG. 2A) or stepped profiles (e.g., similar to the profile in FIG. 2B).

In an embodiment, there may be any number of second vertical holes 331 and grooves 332. In the illustrated embodiment, the first vertical holes 326 and second vertical holes 331 are disposed in an alternating pattern. However, it is to be appreciated that the second vertical holes 331 and the first vertical holes 326 may be disposed in any pattern. Additionally, the number of first vertical holes 326 may be different than the number of second vertical holes 331, and the number of lateral holes 327 may be different than the number of grooves 332. However, in other embodiments, the number of first vertical holes 326 may be the same as the number of second vertical holes 331, and the number of lateral holes 327 may be the same as the number of grooves 332.

Referring now to FIG. 3B, a cross-sectional illustration of an electronic package 300 is shown, in accordance with an embodiment. The electronic package 300 in FIG. 3B is substantially similar to the electronic package 300 in FIG. 3A, with the exception that first vertical holes 326 and lateral holes 327 are omitted. Instead, the body 325 comprises only second vertical holes 331 that each intersect a groove 332 in the second surface 322 of the body 325. Providing additional grooves 332 allows for more cooling fluid (e.g., air from a fan) to contact the device 340. Additionally, conduction is still provided between the device 340 and the body 325 by portions of the second surface 322 between the grooves 332.

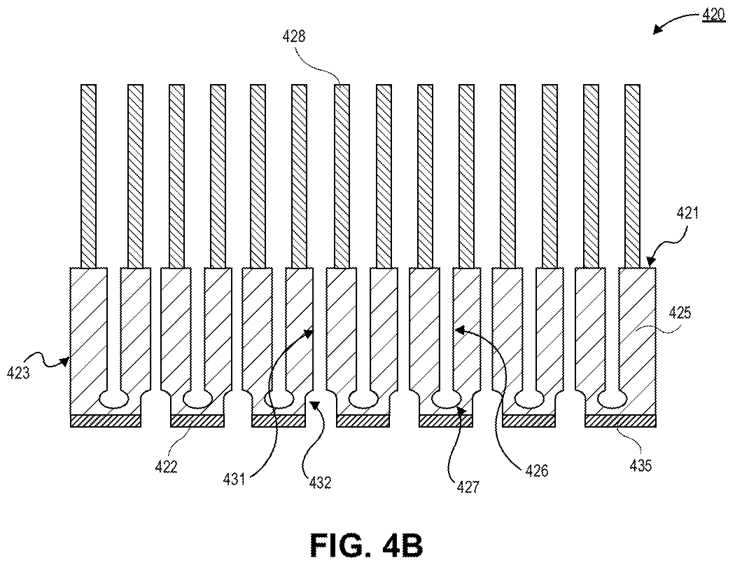

Referring now to FIG. 4A, a cross-sectional illustration of a heatsink 420 is shown, in accordance with an additional embodiment. In an embodiment, the heatsink 420 comprise a thermally conductive body 425, such as copper or aluminum. The body 425 comprises a first surface 421, a second surface 422, and sidewall surfaces 423. In an embodiment, fins 428 extend up from the first surface 421. The fins 428 may be a monolithic part with the body 425 or the fins 428 may be discrete components attached to the body 425.

In an embodiment, vertical holes 426 may be provided into the first surface 421 between the fins 428. The vertical holes 426 may have sidewalls with a substantially vertical profile, as shown in FIG. 4A. In other embodiments, the vertical holes 426 may have sidewalls with a tapered profile or a stepped profile, similar to embodiments described above with respect to FIGS. 2A and 2B. In an embodiment, the vertical holes 426 may each intersect a lateral hole 427. In an embodiment, the vertical holes 426 and the lateral hole 427 may have a diameter that is between approximately 0.5 mm and approximately 2.0 mm.

The lateral hole 427 may extend from a first sidewall 423 to a second sidewall 423. As such, cooling fluid (e.g., air from a fan) passes through the vertical holes 426 and exits the body 425 through the lateral hole 427. In an embodiment, the lateral hole 427 is embedded in the body 425. That is a portion of the body 425 is provided between a bottom of the lateral hole 427 and the second surface 422.

In an embodiment, the heatsink 420 may further comprise a highly ordered pyrolytic graphite (HOPG) coating 435 over a surface of the body 425. Particularly, the HOPG coating 435 may be provided over the second surface 422. In an embodiment, the HOPG coating 435 may have a thickness that is approximately 500 μm or less. In a particular embodiment, the thickness of the HOPG coating 435 may be approximately 250 μm or less.

The HOPG coating 435 may have a high thermal conductivity close to that of diamond. For example, the HOPG coating 435 may have a thermal conductivity that is between approximately 1,700 W/m-K and approximately 1,950 W/m-K. Providing the HOPG coating 435 on the second surface 422 can effectively aid in the spreading of heat from a high-power density or high power package to the body 425, thus lowering the package (not shown) temperature.

HOPG coatings 435 have been shown to significantly improve thermal performance. Particularly, at a power density of approximately 0.25 W/mm² an approximately 6.5% reduction in substrate temperature is shown over a transpiration heatsink without the HOPG coating 435. Furthermore, higher power densities result in even more improvement. For example, at a power density of approximately 1.25 W/mm², an approximately 17% reduction in substrate temperature is shown over a transpiration heatsink without the HOPG coating 435.

In an embodiment, the HOPG coating 435 may be formed with any suitable process. For example, an HOPG coating 435 may be provided onto copper or aluminum through the use of a chemical vapor deposition (CVD) process. In an embodiment, the HOPG coating 435 may be annealed under high pressure and temperature in order to improve the thermal conductivity of the HOPG coating 435.

Referring now to FIG. 4B, a cross-sectional illustration of a heatsink 420 is shown, in accordance with an additional embodiment. The heatsink 420 in FIG. 4B is substantially similar to the heatsink 420 in FIG. 4A, with the exception of there being second vertical holes 431 and grooves 432. The second vertical holes 431 and grooves 432 may be substantially similar to the second vertical holes 331 and grooves 332 in FIG. 3A. As shown, the HOPG coating 435 may be formed over the second surface 422 between the grooves 332. In some embodiments, the HOPG coating 435 may also be formed over surfaces of the grooves 332.

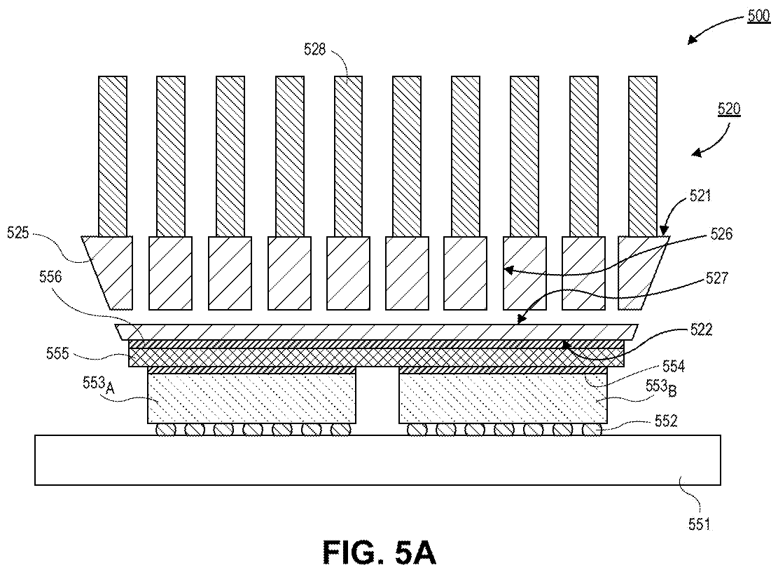

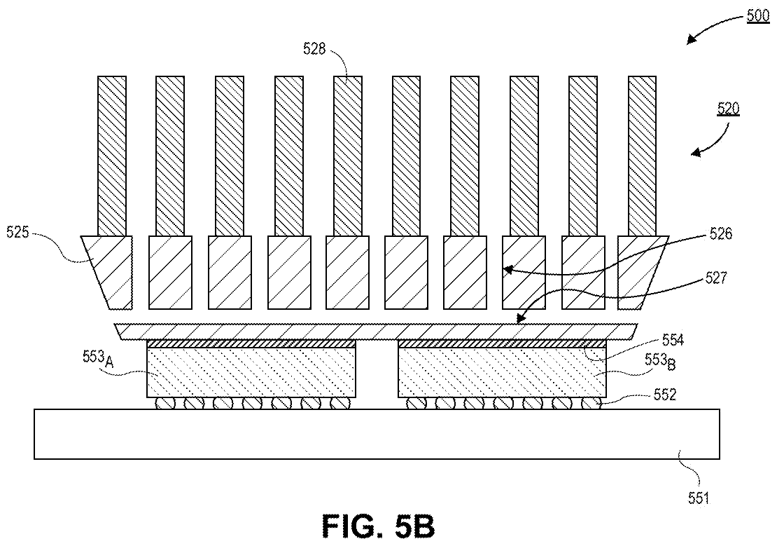

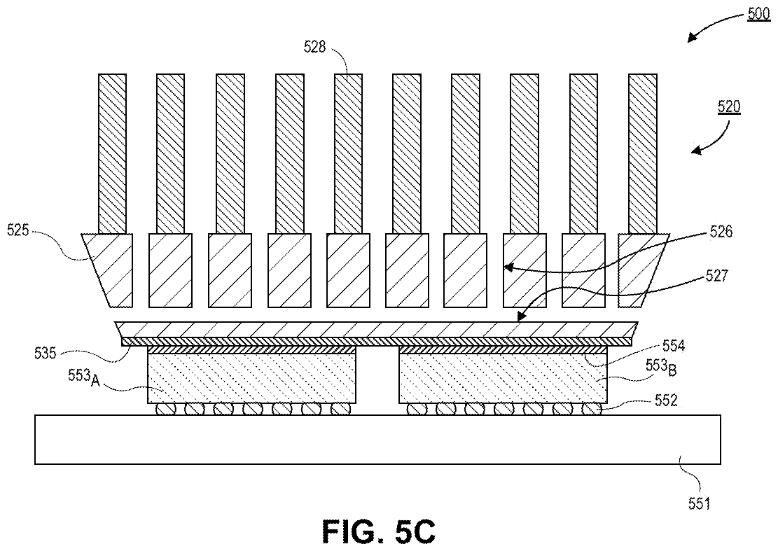

Referring now to FIG. 5A, a cross-sectional illustration of an electronic package 500 is shown, in accordance with an embodiment. In an embodiment, the electronic package 500 comprises a heatsink 520 that is thermally coupled to one or more dies 553_{A} and 553_{B}. The heatsink 520 in FIG. 5A is substantially similar to the heatsink 120 illustrated in FIG. 1A. That is, the heatsink 520 comprises a body 525 with a first surface 521 and a second surface 522. Fins 528 may extend up from the first surface 521. The fins 528 may be a monolithic structure with the body 525 or the fins 528 may be attached to the body 525. Transpiration cooling features are provided in the body 525. For example vertical holes 526 and lateral holes 527 are provided in the body 525. In an embodiment, the vertical holes 526 and the lateral holes 527 may have diameters that are between approximately 0.5 mm and approximately 2 mm. While a heatsink 520 similar to the heatsink 120 in FIG. 1A is shown, it is to be appreciated that the heatsink 520 may be similar to any of the heatsinks described herein. For example, the heatsink 520 may further comprise one or more grooves to provide enhanced cooling of the one or more dies 553_{A} and 553_{B}. Additionally, the vertical holes 526 may include sidewalls with a tapered profile or a stepped profile, as shown in FIGS. 2A and 2B.

In an embodiment, the one or more dies 553_{A} and 553_{B} may be electrically and mechanically coupled to a package substrate 551 by interconnects 552. The interconnects 552 may be copper pillars, solder bumps, or any other suitable first level interconnect (FLI) architecture. In an embodiment, backside surfaces of the one or more dies 553_{A} and 553_{B} may be covered by a first thermal interface material (TIM) 554. The first TIM 554 may provide an interface between the dies 553_{A} and 553_{B} and a heat spreader 555. The heat spreader 555 may comprise a high thermal conductivity material, such as copper. In an embodiment, the heat spreader 555 may interface with the heatsink 520 through a second TIM 556.

The transpiration cooling provided by the vertical holes 526 and the lateral holes 527 provides enhanced cooling capability in order to reduce the temperature of the one or more dies 553_{A} and 553_{B}. For example, the presence of transpiration cooling features may provide an approximately 30% reduction in substrate temperature in temperature reduction compared to a solid body heatsink operating under the same boundary conditions. For example it has been shown that, at a thermal design power (TDP) of 60 W with a power density of approximately 0.25 W/mm², the traditional solid body heatsink has a package temperature of approximately 65° C. and the transpiration cooled package substrate has a temperature of approximately 45° C.

Referring now to FIG. 5B, a cross-sectional illustration of an electronic package 500 is shown, in accordance with an additional embodiment. In an embodiment, the electronic package 500 may be substantially similar to the electronic package 500 in FIG. 5A, with the exception of the removal of the heat spreader 555. The heat spreader 555 may be removed when the body 525 provides sufficient heat spreading capabilities. Removal of the heat spreader 555 allows for the removal of the second TIM 556, and therefore reduces the thermal resistance between the one or more dies 553_{A} and 553_{B} and the heatsink 520. In such an embodiment, the body 525 may be directly coupled to the one or more dies 553_{A} and 553_{B} by a first TIM 554.

Referring now to FIG. 5C, a cross-sectional illustration of an electronic package 500 is shown, in accordance with an additional embodiment. In an embodiment, the electronic package 500 may be substantially similar to the electronic package 500 in FIG. 5B, with the exception of the addition of an HOPG coating 535. In an embodiment, the HOPG coating 535 may have a thickness that is less than approximately 500 μm, or less than approximately 250 μm. The HOPG coating 535 improves the heat spreading of thermal energy from the one or more dies 553_{A} and 553_{B}. As such, the heat spreader 555 may be omitted while still providing excellent thermal performance.

HOPG coatings 535 have been shown to significantly improve thermal performance. Particularly, at a power density of approximately 0.25 W/mm² an approximately 6.5% reduction in substrate temperature is shown over a transpiration heatsink without the HOPG coating 535. Furthermore, higher power densities result in even more improvement. For example, at a power density of approximately 1.25 W/mm², an approximately 17% reduction in substrate temperature is shown over a transpiration heatsink without the HOPG coating 535.

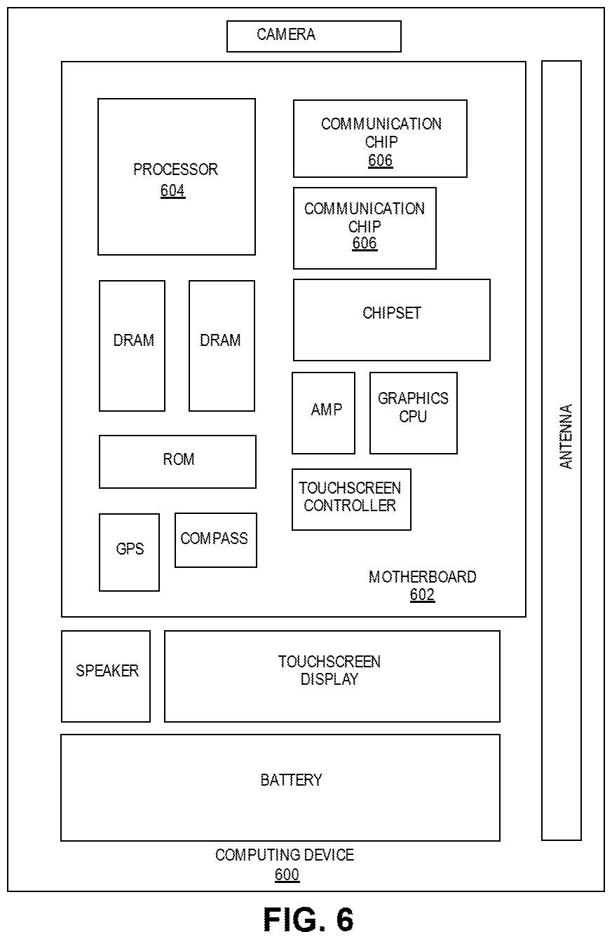

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be coupled to a heatsink that comprises transpiration cooling features, such as vertical holes and lateral holes, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be coupled to a heatsink that comprises transpiration cooling features, such as vertical holes and lateral holes, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a heatsink, comprising: a body with a first surface, a second surface, and a sidewall surface connecting the first surface to the second surface; a first hole into the first surface, wherein the first hole terminates before reaching the second surface; and a second hole into the sidewall surface, wherein the second hole intersects the first hole.

Example 2: the heatsink of Example 1, further comprising: fins extending up from the first surface.

Example 3: the heatsink of Example 1 or Example 2, wherein the first hole terminates at the second hole.

Example 4: the heatsink of Examples 1-3, wherein the first hole has a uniform dimension through an entire depth of the first hole.

Example 5: the heatsink of Examples 1-3, wherein a first dimension of the first hole at the first surface is greater than a second dimension of the first hole at the intersection with the second hole.

Example 6: the heatsink of Example 5, wherein the first hole comprises a tapered profile.

Example 7: the heatsink of Example 5, wherein the first hole comprises a stepped profile.

Example 8: the heatsink of Examples 1-7, further comprising: a third hole into the first surface; and a groove into the second surface, wherein the groove extends from the sidewall surface and intersects with the third hole.

Example 9: the heatsink of Examples 1-8, further comprising: a highly ordered pyrolytic graphite (HOPG) layer over the second surface.

Example 10: the heatsink of Example 9, wherein the HOPG has a thickness of approximately 250 μm or less.

Example 11: a heatsink, comprising: a body with a first surface, a second surface, and sidewall surfaces connecting the first surface to the second surface; fins extending up from the first surface; an array of first holes into the first surface; and an array of second holes into at least one of the sidewall surfaces, wherein individual ones of the first holes intersect with individual ones of the second holes.

Example 12: the heatsink of Example 11, wherein a plurality of first holes intersect with a single one of the second holes.

Example 13: the heatsink of Example 11 or Example 12, wherein the second holes extend through an entire width of the body from a first sidewall surface to a second sidewall surface that is on an opposite end of the body from the first sidewall surface.

Example 14: the heatsink of Examples 11-13, further comprising: an array of third holes into the first surface; and an array of grooves into the second surface, wherein individual ones of the third holes intersect individual ones of the grooves.

Example 15: the heatsink of Example 14, wherein the grooves are substantially parallel to the second holes.

Example 16: the heatsink of Example 15, wherein the grooves and the second holes are arranged in an alternating pattern.

Example 17: the heatsink of Examples 11-16, wherein the first holes comprise a tapered profile.

Example 18: the heatsink of Examples 11-16, wherein the first holes comprise a stepped profile.

Example 19: the heatsink of Examples 11-18, further comprising: a highly ordered pyrolytic graphite (HOPG) layer over the second surface.

Example 20: the heatsink of Example 19, wherein the HOPG has a thickness of approximately 250 μm or less.

Example 21: an electronic package, comprising: a package substrate; a die over the package substrate; and a heatsink thermally coupled to the die, wherein the heatsink comprises: a body; fins extending out from the body; and holes into the body, wherein the holes allow for transpiration cooling.

Example 22: the electronic package of Example 21, wherein the holes comprise: first holes into a first surface of the body, wherein the first surface faces away from the die; and second holes into a sidewall surface of the body, wherein individual ones of the first holes intersect individual ones of the second holes.

Example 23: the electronic package of Example 22, wherein the first holes comprise a tapered profile or a stepped profile.

Example 24: the electronic package of Examples 21-23, wherein the heatsink further comprises: a highly ordered pyrolytic graphite (HOPG) layer over a surface of the body facing the die.

Example 25: the electronic package of Example 24, wherein the die is thermally coupled to the HOPG by only a thermal interface material.

What is claimed is:

1. A heatsink, comprising:
a body with a first surface, a second surface, and a sidewall surface connecting the first surface to the second surface;
a first hole into the first surface, wherein the first hole terminates before reaching the second surface; and
a second hole into the sidewall surface, wherein the second hole intersects the first hole.

2. The heatsink of claim 1, further comprising:
fins extending up from the first surface.

3. The heatsink of claim 1, wherein the first hole terminates at the second hole.

4. The heatsink of claim 1, wherein the first hole has a uniform dimension through an entire depth of the first hole.

5. The heatsink of claim 1, wherein a first dimension of the first hole at the first surface is greater than a second dimension of the first hole at the intersection with the second hole.

6. The heatsink of claim 5, wherein the first hole comprises a tapered profile.

7. The heatsink of claim 5, wherein the first hole comprises a stepped profile.

8. The heatsink of claim 1, further comprising:
a third hole into the first surface; and
a groove into the second surface, wherein the groove extends from the sidewall surface and intersects with the third hole.

9. The heatsink of claim 1, further comprising:
a highly ordered pyrolytic graphite (HOPG) layer over the second surface.

10. The heatsink of claim 9, wherein the HOPG has a thickness of approximately 250 μm or less.

11. A heatsink, comprising:
a body with a first surface, a second surface, and sidewall surfaces connecting the first surface to the second surface;
fins extending up from the first surface;
an array of first holes into the first surface; and
an array of second holes into at least one of the sidewall surfaces, wherein individual ones of the first holes intersect with individual ones of the second holes.

12. The heatsink of claim 11, wherein a plurality of first holes intersect with a single one of the second holes.

13. The heatsink of claim 11, wherein the second holes extend through an entire width of the body from a first sidewall surface to a second sidewall surface that is on an opposite end of the body from the first sidewall surface.

14. The heatsink of claim 11, further comprising:
an array of third holes into the first surface; and
an array of grooves into the second surface, wherein individual ones of the third holes intersect individual ones of the grooves.

15. The heatsink of claim 14, wherein the grooves are substantially parallel to the second holes.

16. The heatsink of claim 15, wherein the grooves and the second holes are arranged in an alternating pattern.

17. The heatsink of claim 11, wherein the first holes comprise a tapered profile.

18. The heatsink of claim 11, wherein the first holes comprise a stepped profile.

19. The heatsink of claim 11, further comprising:
a highly ordered pyrolytic graphite (HOPG) layer over the second surface.

20. The heatsink of claim 19, wherein the HOPG has a thickness of approximately 250 μm or less.

21. An electronic package, comprising:
a package substrate;
a die over the package substrate; and
a heatsink thermally coupled to the die, wherein the heatsink comprises:
a body;
fins extending out from the body; and
holes into the body, wherein the holes allow for transpiration cooling.

22. The electronic package of claim 21, wherein the holes comprise:
first holes into a first surface of the body, wherein the first surface faces away from the die; and
second holes into a sidewall surface of the body, wherein individual ones of the first holes intersect individual ones of the second holes.

23. The electronic package of claim 22, wherein the first holes comprise a tapered profile or a stepped profile.

24. The electronic package of claim 21, wherein the heatsink further comprises:
a highly ordered pyrolytic graphite (HOPG) layer over a surface of the body facing the die.

25. The electronic package of claim 24, wherein the die is thermally coupled to the HOPG by only a thermal interface material.
